(19) United States
(12) Patent Application Publication
(10) Pub. No.: US 2025/0140600 A1
(43) Pub. Date: May 1, 2025

(54) PROCESS FOR FABRICATING A DOUBLE SEMICONDUCTOR-ON-INSULATOR STRUCTURE

(71) Applicant: Soitec, BERNIN (FR)

(72) Inventors: Carine Duret, BERNIN (FR); Ludovic Ecarnot, BERNIN (FR); Charlene Porta, BERNIN (FR)

(21) Appl. No.: 18/834,482

(22) PCT Filed: Jan. 30, 2023
(86) PCT No.: PCT/FR2023/050115

§ 371 Date: Jul. 30, 2024

(30) Foreign Application Priority Data
Jan. 31, 2022 (FR) FR2200850

(51) Int. Cl. H01L 21/762; H10D 86/00

(52) U.S. Cl. CPC H01L 21/76254; H10D 86/201

(57) ABSTRACT

A method is used to fabricate a double semiconductor-on-insulator structure comprising, from a back side to a front side of the structure: a handle substrate, a first electrically insulating layer, a first single-crystal semiconductor layer, a second electrically insulating layer and a second single-crystal semiconductor layer. The method comprises:—a first step of formation of an oxide layer on the front and back sides of the handle substrate, to form the first electrically insulating layer and an oxide layer on the back side of the handle substrate, —a first step of layer transfer, to transfer the first single-crystal semiconductor layer, —a second step of formation of an oxide layer, to form the second electrically insulating layer, and —a second step of layer transfer, to transfer the second single-crystal semiconductor layer.

### CROSS-REFERENCE TO RELATED APPLICATIONS

This application is a national phase entry under 35 U.S.C. § 371 of International Patent Application PCT/FR2023/050115, filed Jan. 30, 2023, designating the United States of America and published as International Patent Publication WO 2023/144495 A1 on Aug. 3, 2023, which claims the benefit under Article 8 of the Patent Cooperation Treaty of French Patent Application Serial No. FR2200850, filed Jan. 31, 2022.

### TECHNICAL FIELD

The present disclosure relates to a process for fabricating a double semiconductor-on-insulator structure.

### BACKGROUND

Semiconductor-on-insulator structures are multilayer structures comprising a handle substrate, which is generally made of a semiconductor such as silicon, an electrically insulating layer arranged on the handle substrate, which is generally an oxide layer such as a layer of silicon oxide and a semiconductor layer arranged on the insulating layer, which is generally a silicon layer. Such structures are referred to as SeOI structures (SeOI standing for semiconductor-on-insulator), or more particularly SOI structures when the semiconductor is silicon (SOI standing for silicon-on-insulator). The oxide layer is located between the substrate and the semiconductor layer. The oxide layer is thus said to be “buried,” and is called the “BOX” (BOX standing for buried oxide). In the rest of the text, the term “SOI” will be employed to designate semiconductor-on-insulator structures generally.

In addition to SOI structures comprising one BOX layer and one semiconductor layer arranged on the BOX layer, “double SOI” structures have been produced. The structures referred to as “double SOI” structures comprise a handle substrate, a first oxide layer or lower buried oxide layer arranged on the handle substrate, a first semiconductor layer or lower semiconductor layer arranged on the first oxide layer, a second oxide layer or an upper buried oxide layer arranged on the first semiconductor layer and a second semiconductor layer or upper semiconductor layer arranged on the second oxide layer. In this double SOI structure, the first oxide layer and the first semiconductor layer form the first SOI, arranged in a lower portion of the structure, whereas the second oxide layer and the second semiconductor layer form the second SOI, arranged in an upper portion of the structure.

One known process for fabricating an SOI structure is the process called SMART CUT™. The SMART CUT™ process comprises implantation of atomic species, such as hydrogen (H) and/or helium (He), to create a weakened region within a donor substrate, bonding the donor substrate to the receiver substrate then detaching the donor substrate level with the weakened region so as to transfer a thin layer from the donor substrate to the receiver substrate. The donor substrate and the receiver substrate preferably take the form of wafers of 300 mm diameter. The donor substrate is a semiconductor substrate the surface of which has been oxidized beforehand: the H and/or He atoms are implanted, through the oxide layer, to a given depth in the bulk of the semiconductor. The bonding is between the surface of the receiver substrate and the surface of the oxide layer of the donor substrate.

One proposed way of obtaining a double SOI structure is to implement two successive SMART CUT™ processes using, in the second SMART CUT™ process, the SOI obtained following the first SMART CUT™ process as receiver substrate, and a second semiconductor substrate the surface of which has been oxidized beforehand as donor substrate. In the final double SOI structure, the oxide layer and the semiconductor layer of the first SOI, which were obtained following the first SMART CUT™ process, form the lower oxide layer and the lower semiconductor layer, respectively. The oxide layer and the semiconductor layer produced from the second donor substrate following the second SMART CUT™ process form the upper oxide layer and the upper semiconductor layer of the obtained double SOI, respectively.

For a given depth of the weakened region within a donor substrate, the thickness of the semiconductor layer intended to be transferred is limited by the thickness of the oxide layer present on the surface of the donor substrate. Specifically, the maximum thickness through which the hydrogen and/or helium atoms are able to penetrate into the donor substrate covered by the oxide layer is set by the maximum energy of the implanted device. This thickness depends on the thickness of oxide passed through by the implanted atoms. It typically remains about a few hundred nanometers of silicon. The “double SMART CUT™” process described above does not therefore allow large thicknesses to be obtained both for the semiconductor layers and for the oxide layers. Double SeOI structures having oxide layers and semiconductor layers of large thicknesses (for example, about a few hundred nanometers each) are however of interest in certain applications, in particular, in photonics.

Furthermore, the effectiveness of the bond formed in the second SMART CUT™ process is determined by the quality of the surface of the SOI serving as receiver substrate. Surface treatments, such as, for example, heat treatments, may be carried out before the second donor substrate is bonded in order, in particular, to decrease the roughness of the surface of the SOI serving as receiver substrate. However, at the end of such heat treatments, deformation (or wrap) may be observed in the wafer formed by the first SOI and/or by the double SOI. The wafers are all the more sensitive to deformation as they have a large diameter, in particular, a diameter of 300 mm in favored applications. Industrial equipment for fabricating and treating semiconductor wafers are designed to handle planar wafers. Moreover, using a strained deformed (or wrapped) wafer as receiver substrate when forming the second bond with the second donor substrate may lead to defects being generated during this second bonding operation, and therefore to a bond of poor quality.

### BRIEF SUMMARY

One aim of the present disclosure is to produce multilayer structures of double semiconductor-on-insulator type that are such that the thicknesses of the semiconductor layers and of the electrically insulating layers are sufficient for certain applications in photonics.

Another aim of the present disclosure is to limit deformation (or wrapping) in the wafer after any heat treatments, in particular, surface treatments, carried out in the course of the process used to fabricate the multilayer structure of double semiconductor-on-insulator type.

To this end, the present disclosure provides a process for fabricating a double semiconductor-on-insulator structure comprising, in succession, from a back side to a front side of the structure: a handle substrate, a first electrically insulating layer, a first single-crystal semiconductor layer, a second electrically insulating layer and a second single-crystal semiconductor layer, the process being characterized in that it comprises:
a first step of formation of an oxide layer on the front and back sides of the handle substrate, to form the first electrically insulating layer on the front side of the handle substrate, and an oxide layer on the back side of the handle substrate,
a first step of layer transfer, to transfer the first single-crystal semiconductor layer from a first donor substrate to the first electrically insulating layer, so as to form a first semiconductor-on-insulator substrate, comprising successively, from the back side to the front side of the first semiconductor-on-insulator substrate, the oxide layer, the handle substrate, the first electrically insulating layer and the first single-crystal semiconductor layer,
a second step of formation of an oxide layer on the front side of the first semiconductor-on-insulator substrate, to form the second electrically insulating layer and thicken the oxide layer,
a second step of layer transfer, to transfer the second single-crystal semiconductor layer from a second donor substrate to the second electrically insulating layer, so as to form the double semiconductor-on-insulator substrate,
the oxide layer contributing to the preservation of the flatness of the handle substrate during the first and second transfer steps.

Since the various layers of the double SOI structure have different coefficients of thermal expansion, such a structure may be subject to deformation. Such deformation, in particular, arises at the end of the various heat treatments that may be applied to the structure, during cooling of the structure. Formation of an oxide layer on the back side of the double SOI structure according to the present disclosure advantageously allows a structural balance to be achieved, so that the effects of thermal expansion cancel out in the structure as a whole, thus greatly limiting the deformation to which it is subjected.

According to other features of the present disclosure, which are optional, and which may be implemented alone, or in combination when this is technically possible:
the thickness of the first electrically insulating layer is between 100 nm and 3000 nm,
in the final double semiconductor-on-insulator structure obtained, the thickness of the first single-crystal semiconductor layer is between 50 nm and 500 nm,
in the final double semiconductor-on-insulator structure obtained, the thickness of the second electrically insulating layer is between 100 nm and 1100 nm,
in the final double semiconductor-on-insulator structure obtained, the thickness of the second single-crystal semiconductor layer is between 50 nm and 500 nm,
the step of transfer of the first single-crystal semiconductor layer from a first donor substrate to the first electrically insulating layer is carried out using a process comprising, in succession, implantation of atomic species to create, within the first donor substrate, a weakened region bounding the first single-crystal semiconductor layer, bonding the side of the first donor substrate of the first single-crystal semiconductor layer that underwent implantation to the first electrically insulating layer, and splitting the first donor substrate level with the weakened region,
the remnant of the first donor substrate resulting from splitting is used to form the second donor substrate,
the process of transfer of the first single-crystal semiconductor layer from a first donor substrate to the first electrically insulating layer further comprises oxidation of the surface of the first donor substrate prior to the implantation of atomic species within the first donor substrate, thus forming a first protective oxide layer so that the atomic species are implanted through the first protective oxide layer,
the first protective oxide layer formed on the surface of the first donor substrate is removed after the atomic species have been implanted and before the first donor substrate is bonded to the first electrically insulating layer,
the step of transfer of the second single-crystal semiconductor layer from a second donor substrate to the second electrically insulating layer is carried out using a process comprising, in succession, implantation of atomic species to create, within the second donor substrate, a weakened region bounding the second single-crystal semiconductor layer, bonding the side of the second donor substrate of the second single-crystal semiconductor layer that underwent implantation to the second electrically insulating layer, and splitting the second donor substrate level with the weakened region,
the process of transfer of the second single-crystal semiconductor layer from a second donor substrate to the second electrically insulating layer further comprises oxidation of the surface of the second donor substrate prior to the implantation of atomic species within the second donor substrate, thus forming a second protective oxide layer so that the atomic species are implanted through the second protective oxide layer,
the second protective oxide layer formed on the surface of the second donor substrate is removed after the atomic species have been implanted and before the second donor substrate is bonded to the second electrically insulating layer,
the process further comprises a step of carrying out a process of treatment of the surface of the first single semiconductor-on-insulator substrate, before the second step of formation of an oxide layer on the surface of this first single semiconductor-on-insulator substrate, the surface-treatment process being characterized by:
   a first step of rapid thermal annealing,
   a second step of thermal oxidation followed by a deoxidation,
   a third step of long-duration heat treatment or a third step of rapid thermal annealing, the long-duration heat treatment and the rapid thermal annealing being carried out at a temperature above 1000° C. in a non-oxidizing atmosphere, and
   a fourth step of chemical-mechanical polishing.
the handle substrate and each donor substrate preferably take the form of wafers of 300 mm diameter.

### BRIEF DESCRIPTION OF THE DRAWINGS

Other features and advantages of the present disclosure will emerge from the detailed description that follows, with reference to the appended drawings, in which:

FIG. 1 shows a cross-sectional view of a handle substrate;

FIG. 2 shows a cross-sectional view of the handle substrate after a first step of oxidation of the front and back sides of the handle substrate;

FIG. 3 shows a cross-sectional view of a first layer transfer from a first donor substrate to the front side of the handle substrate;

FIG. 4 shows a cross-sectional view of the intermediate structure obtained after bonding the first donor substrate;

FIG. 5 shows a cross-sectional view of the intermediate semiconductor-on-insulator structure obtained following the first layer transfer;

FIG. 6 shows a cross-sectional view of the intermediate structure obtained after a second step of oxidation on the front and back sides of the semiconductor-on-insulator substrate of FIG. 5;

FIG. 7 shows a cross-sectional view of a second layer transfer from a second donor substrate to the front side of the intermediate structure of FIG. 6;

FIG. 8 shows a cross-sectional view of the structure obtained after bonding of the second donor substrate; and

FIG. 9 shows the final double semiconductor-on-insulator structure obtained after the second layer transfer.

For the sake of legibility, the drawings have not necessarily been drawn to scale.

### DETAILED DESCRIPTION

The present disclosure provides a process for fabricating a double semiconductor-on-insulator substrate structure comprising, from the back side to the front side, a handle substrate, a first buried oxide layer corresponding to a first electrically insulating layer, a first single-crystal semiconductor layer, a second buried oxide layer corresponding to a second electrically insulating layer and a second single-crystal semiconductor layer.

The first electrically insulating layer and the first single-crystal semiconductor layer together form a first semiconductor-on-insulator structure called the lower SOI structure. The second electrically insulating layer and the second single-crystal semiconductor layer together form a second semiconductor-on-insulator structure called the upper SOI structure. Furthermore, the handle substrate advantageously comprises, on its back side, an oxide layer allowing the deformation generated in the handle during implementation of the process that is the subject of the present disclosure to be limited.

The sum of the thicknesses of the layers forming the double semiconductor-on-insulator substrate structure obtained using the process that is the subject of the present disclosure is high. In particular:
the thickness of the first electrically insulating layer is preferably larger than 100 nm,
the thickness of the first single-crystal semiconductor layer is preferably larger than 50 nm and smaller than 500 nm,
the thickness of the second electrically insulating layer is preferably larger than 100 nm and smaller than 1100 nm,
the thickness of the second single-crystal semiconductor layer is preferably larger than 50 nm and smaller than 500 nm.

In the context of an application in photonics, for example, such layer thicknesses allow passive photonic components (such as waveguides) or active photonic components (such as resonators) to be produced.

Such thicknesses are not achievable using the conventional SMART CUT™ process, in which the single-crystal semiconductor layer is delineated via implantation of atomic species in a donor substrate covered with an oxide layer intended to form the electrically insulating layer in the SOI structure. Specifically, industrial implantation devices have a maximum energy that prevents hydrogen and/or helium atoms from passing through oxide layers and single-crystal semiconductor layers of such thickness.

### First Oxidation Step

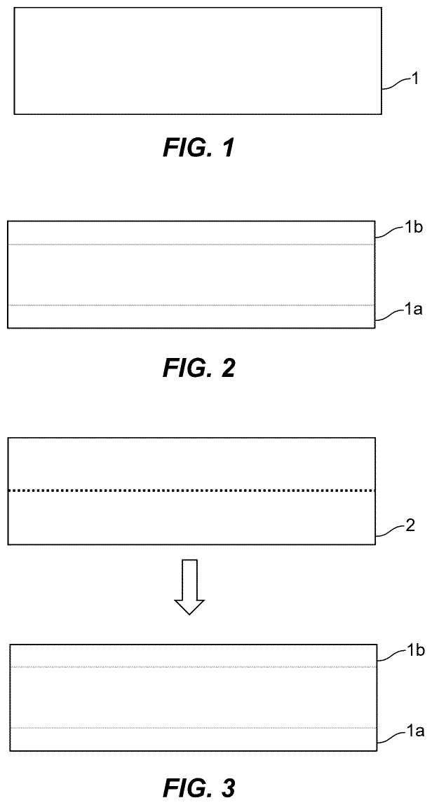

With reference to FIG. 1, a handle substrate 1 is initially provided. The handle substrate 1 takes the form of a semiconductor wafer, and preferably of a wafer of 300 mm diameter and of 775 μm thickness. The handle substrate 1 is, for example, a silicon wafer, and preferably a high resistivity silicon wafer with a high content of interstitial oxygen Oi, i.e., what is commonly referred to as an HR substrate or high Oi substrate.

In a first step shown in FIG. 2, the front and back sides of the substrate 1 and the edges of the substrate 1 are oxidized.

During oxidation of the front side, the handle substrate 1 is partially consumed to form the first electrically insulating oxide layer 1b. By way of example, if the handle substrate is a silicon substrate, the first electrically insulating oxide layer 1b is therefore a silicon-oxide layer. The oxidation conditions are controlled to obtain a first electrically insulating oxide layer 1b having the desired thickness.

Such an oxidation operation may, for example, be carried out by heating the handle substrate 1 to a temperature between 800° C. and 1100° C. under an oxidizing atmosphere for a few minutes to several hours, to obtain a first electrically insulating oxide layer 1b of large thickness between 100 nm and 3000 nm.

The simultaneous oxidation of the back side advantageously leads to formation, on the back side of the handle, of an oxide layer la that has substantially the same thickness as the first electrically insulating oxide layer 1b formed on the front side. The oxide layer la has a coefficient of thermal expansion lower than that of the unoxidized handle substrate 1. In the rest of the process, in particular, at the end of implemented heat treatments, the presence of the oxide layer 1a on the back side of the handle substrate 1 allows the deformation in the handle substrate 1 to be limited, and thus the quality of the subsequent bond of the new layers to the front side of the structure to be improved.

The thickness of the oxide layer 1a obtained under the oxidation conditions described above is identical to the thickness of the first electrically insulating layer 1b. In the course of any subsequent heat treatments and of the cooling period that follows the treatments, an oxide layer 1a of such a thickness allows the effects of thermal expansion, as experienced by the structure on the whole, to be balanced out and therefore deformation in the structure to be avoided. First step of layer transfer

With reference to FIG. 3, a first donor substrate including a first single-crystal semiconductor layer 2 is provided. The first donor substrate is a single-crystal semiconductor substrate, for example, a substrate of single-crystal silicon. The first donor substrate takes the form of a wafer of same diameter as the handle substrate 1 and of thickness between 670 μm and 775 μm.

According to one embodiment, a first layer transfer is carried out using the SMART CUT™ process. A weakened region (dotted line in FIG. 3) is formed in the first donor substrate, so as to delineate the first semiconductor layer 2. The weakened region is formed in the donor substrate at a predefined depth that substantially corresponds to the thickness of the first semiconductor layer 2 to be transferred. Preferably, the weakened region is created by implantation of hydrogen and/or helium atoms in the substrate that will donate the semiconductor layer.

Since the first electrically insulating layer 1b was formed from the receiver substrate, i.e., the handle substrate 1, and not from the first donor substrate, the thickness of the transferred first semiconductor layer 2 is limited only by the maximum energy of the implantation device, which is about 100 keV. Such a maximum implantation energy corresponds to a maximum thickness of the transferred first semiconductor layer 2 of about 600 nm, depending on the species implanted. The present disclosure therefore allows a first semiconductor layer 2 of large thickness to be transferred while having a first electrically insulating layer 1b also having a large thickness.

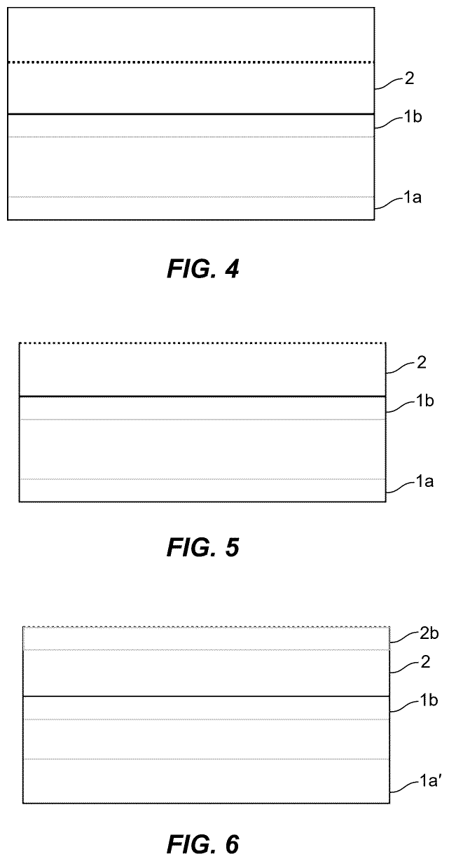

With reference to FIG. 4, the first semiconductor layer 2 is then transferred by bonding the side of the first donor substrate that underwent implantation to the first electrically insulating oxide layer 1b and by detaching the rest of the donor substrate along the weakened region (see FIG. 5). The detachment along the weakened region may be triggered by a mechanical action and/or a supply of thermal energy. In the first step of layer transfer, at least one portion of the oxide layer on the back side of the handle substrate is preserved, so as to limit problems related to wafer deformation.

Before atomic species are implanted into the first donor substrate, a very small thickness of the surface of the first donor substrate, for example, a thickness between 20 and 30 nm, may optionally be oxidized. Specifically, the implantation of atomic species in the first donor substrate is better if it is done through the very thin oxide layer, which is an amorphous phase, rather than in the single-crystal material directly. Furthermore, the very thin oxide layer protects the first semiconductor layer 2 during the atomic implantation. In this case, the very thin oxide layer on the surface of the first donor substrate is removed after the atomic species have been implanted and before the first donor substrate is bonded to the first electrically insulating layer 1b.

The oxidation of the very small thickness of the surface of the first donor substrate may be achieved by applying a temperature between 800° C. and 1000° C. for a few minutes to a few tens of minutes under oxidizing atmosphere.

Alternatively to the SMART CUT™ process described above, the first layer transfer may be achieved by thinning the donor substrate from the side thereof opposite the side bonded to the handle substrate, until the thickness desired for the first semiconductor layer is obtained.

Following the first layer transfer, with reference to FIG. 5, a first semiconductor-on-insulator substrate comprising the first electrically insulating layer 1b and the first single-crystal semiconductor layer 2 is obtained. The semiconductor-on-insulator substrate has a surface roughness that depends on the process used by the layer transfer. Various treatments may be applied to the free surface of the first single-crystal semiconductor layer 2 to allow a good bond quality and to limit the formation of holes during the bonding of the second donor substrate described below. To decrease the defect level and roughness of the surface, for example, a smoothing heat treatment, a sacrificial oxidation and/or a cleaning process may be performed. This surface treatment allows the quality of the subsequent bond with the second donor substrate in the second step of layer transfer to be improved.

At the end of the heat treatments and when the structure has returned to thermal equilibrium (room temperature, for example), the existence of the oxide layer 1a (having a predefined thickness) makes it possible to preserve structural balance, the planarity of the substrate and thus the quality of the bond with the second donor substrate.

### Second Oxidation Step

The front and back sides of the first semiconductor-on-insulator substrate are then oxidized, as shown in FIG. 6.

The oxidation on the front side leads to a partial consumption of the first single-crystal semiconductor layer 2, and therefore to a decrease in the thickness of the first single-crystal semiconductor layer 2 transferred beforehand, and to formation of the second electrically insulating layer 2b. By way of example, if the first donor substrate is a silicon substrate, the second electrically insulating oxide layer 2b is therefore a silicon-oxide layer.

The oxidation on the back side leads to an increase in the thickness of the initial oxide layer 1a so as to form a thickened oxide layer 1a′.

The second oxidation step may, for example, be carried out by annealing the semiconductor-on-insulator structure obtained following the first layer transfer at a temperature between 800° C. and 1100° C. under an oxidizing atmosphere for a few minutes to several hours, to obtain a second electrically insulating oxide layer 2b of thickness between 100 nm and 1100 nm.

The thickness of the first semiconductor layer 2 in the final structure is essentially the thickness of the transferred first semiconductor layer 2 minus the thickness of the first semiconductor layer 2 consumed to form the second electrically insulating layer 2b. The maximum thickness of the first semiconductor layer 2 at the moment of transfer is limited only by the implantation process, and it is generally smaller than 2 μm, and preferably about 600 nm. The thickness of the first semiconductor layer 2 in the final structure may therefore preferably be between 50 nm and 1 μm, and even more preferably between 50 and 500 nm.

By way of example, if the thickness of the transferred first semiconductor layer 2 is 600 nm, the surface treatments to improve the surface quality of the first semiconductor layer 2 consume semiconductor over about 100 nm of thickness. The second oxidation step may then consume a thickness of 450 nm of semiconductor, to leave a first semiconductor layer 2 of a thickness of 50 nm and to form a second electrically insulating layer 2b of about 1000 nm in thickness.

Prior to the second layer transfer, the free surface of the second electrically insulating layer 2b may advantageously be cleaned and/or chemically-mechanically polished.

### Second Step of Layer Transfer

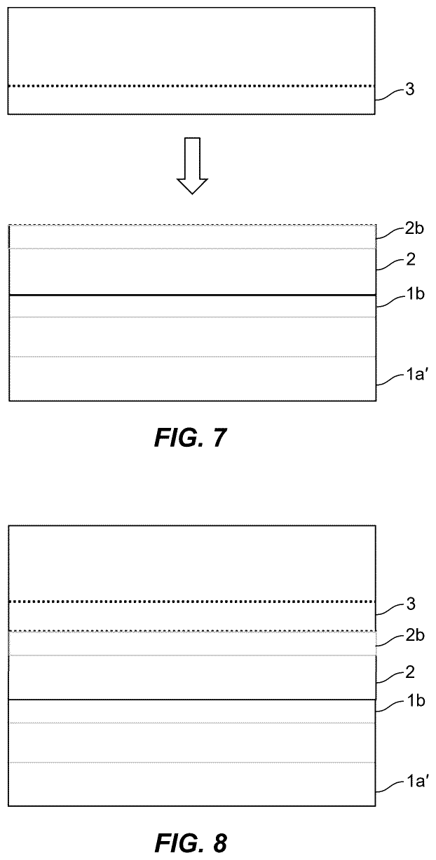

Moreover, with reference to FIG. 7, a second donor substrate including a second single-crystal semiconductor layer 3 is provided. Just like the first donor substrate, the second donor substrate is a single-crystal semiconductor substrate, for example, a substrate of single-crystal silicon. The second donor substrate takes the form of a wafer of same diameter as the handle substrate 1 and the first donor substrate. Optionally, the remnant of the first donor substrate may be recycled to form the second donor substrate. To this end, the remnant of the first donor substrate is processed to remove defects related to the implantation and detachment, and to give it a surface state compatible with a new bonding operation.

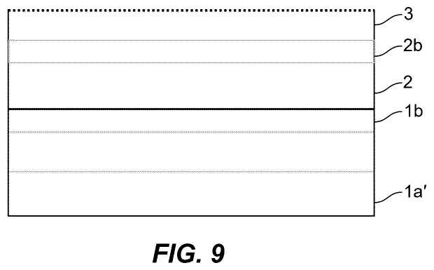

According to one embodiment, the second layer transfer is carried out using the SMART CUT™ process. A weakened region delineating the second single-crystal semiconductor layer 3 is formed in this second donor substrate (see dotted line in FIG. 7). The weakened region may be formed in the same way used to delineate the first single-crystal semiconductor layer 2 within the first donor substrate. With reference to FIG. 8, the second single-crystal semiconductor layer 3 is transferred by bonding the side of the second donor substrate that underwent implantation to the second electrically insulating layer 2b. With reference to FIG. 9, the rest of the second donor substrate is removed by splitting the latter along the weakened region.

Before the weakened region is formed in the second donor substrate, a very small thickness of the surface of the second donor substrate, for example, a thickness between 20 and 30 nm, may optionally be oxidized. The very thin oxide layer on the surface of the second donor substrate is preferably removed after the weakened region has been formed and before the second donor substrate is bonded to the second electrically insulating layer 2b.

Just as with the first donor substrate, the oxidation of a very small thickness of the surface of the second donor substrate may be achieved by applying a temperature between 800° C. and 1000° C. for a few minutes to a few tens of minutes under oxidizing atmosphere.

Alternatively, the second layer transfer may be achieved by thinning the second donor substrate from the side thereof opposite the side bonded to the second electrically insulating layer 2b, until the thickness desired for the second semiconductor layer 3 is obtained.

In the second step of layer transfer, at least one portion of the oxide layer on the back side of the handle substrate is preserved, so as to limit problems related to deformation in the wafer.

Following the second layer transfer, a second semiconductor-on-insulator structure comprising the second electrically insulating layer 2b and the second single-crystal semiconductor layer 3 is obtained, which structure forms the upper semiconductor-on-insulator structure of the final double semiconductor-on-insulator structure (see FIG. 9).

Since the second electrically insulating layer 2b was formed from a second receiver substrate, i.e., by the first semiconductor-on-insulator substrate oxidized on its front side, and not from the second donor substrate, the thickness of the transferred second semiconductor layer 3 is limited only by the maximum energy of the implantation process. Such a maximum implantation energy corresponds to a thickness of the second semiconductor layer 3 of about 600 nm, depending on the species implanted. The present disclosure therefore allows a second semiconductor layer 3 of large thickness to be obtained while having a second electrically insulating layer 2b also having a large thickness.

Optionally, various treatments may be carried out on the free surface of the second semiconductor layer 3, for example, to perfect the thickness of the layer or to improve the quality of the free surface with a view to potential subsequent functionalizations. In the case of heat treatments, the oxide layer 1a on the back side of the handle substrate 1 advantageously limits deformation in the double semiconductor-on-insulator structure.

### Optional Surface Treatments

Optionally, the free surface of the first semiconductor layer 2 may be treated before the oxidation step leading to formation of the second electrically insulating layer 2b, to decrease the defect level and roughness thereof. Decreasing the defect level and roughness of the surface of the first semiconductor layer 2 allows a second electrically insulating layer 2b the surface of which also has characteristics compatible with formation of a high-quality subsequent bond, and, in particular, a low defect level and a low roughness, to be generated. Alternatively or in addition, the free surface of the second electrically insulating layer 2b may be treated before the second layer transfer, a chemical-mechanical polish and/or a clean, for example, being carried out. These surface treatments improve the bond of the second single-crystal semiconductor layer 3, in particular, by limiting the formation of holes and other defects.

The treatment of the free surface of the first semiconductor layer 2 before the second oxidation step, and/or of the second electrically insulating layer 2b before the second step of layer transfer, may itself involve carrying out a process made up of a plurality of steps. One example of a process preferably used to treat the free surface of the first single-crystal semiconductor layer 2 (before formation of the second electrically insulating oxide layer 2b) comprises the following successive steps:
(E1) rapid thermal annealing,
(E2) an oxidation/deoxidation sequence,
(E3) long-duration thermal annealing (a.k.a. batch annealing),
(E4) chemical-mechanical polishing.

Alternatively, the step (E3) of long-duration thermal annealing is replaced by a step (E3′) of rapid thermal annealing. Also alternatively, steps (E1), (E2) and (E3/E3′) of the process are carried out on the free surface of the first single-crystal semiconductor layer 2 and step (E4) may be carried out before and after the second oxidation step (to form the second electrically insulating oxide layer 2b), on the surface of the first single-crystal semiconductor layer 2 and on the surface of the second electrically insulating layer 2b, respectively.

By “rapid thermal annealing,” what is meant is annealing for a time of a few seconds or a few tens of seconds, under controlled atmosphere. Such annealing is commonly designated by the acronym RTA. The rapid thermal annealing (E1) is carried out at a temperature between 1100° C. and 1250° C. for a few seconds to around one hundred seconds. The rapid thermal annealing (E1) is carried out under an atmosphere containing a mixture of hydrogen and/or argon.

The oxidation/deoxidation step (E2) must be understood to be a sequence comprising the sequence of the following operations:
a thermal oxidation operation (E2a),
a deoxidation operation (E2b).

The oxidation operation (E2a) may, for example, be carried out by heating the structure at a temperature between 800° C. and 1100° C. for a few minutes to a few hours under oxidizing atmosphere. The deoxidation operation (E2b) may, for example, be carried out by exposing the front side of the structure to an HF solution (HF standing for hydrofluoric acid) for a few seconds to a few minutes, to remove the oxide layer formed on the front side, without removing the oxide layer present on the back side of the structure. This oxidation/deoxidation step allows the thickness of the semiconductor layer to be adjusted through consumption of a surface segment of the silicon by oxidation.

The long-duration thermal annealing or batch annealing corresponds to thermal annealing for a time of about a few minutes to a few hours (generally longer than 15 minutes), advantageously in a furnace under controlled atmosphere. The furnace annealing (E3) is carried out at a temperature between 1050° C. and 1250° C. Furthermore, the furnace annealing (E3) is, for example, carried out under inert atmosphere, under argon, for example.

In the course of the chemical-mechanical polishing or CMP, the surface to be polished is modified using a chemical agent, for example, a suspension of colloidal silica particles in a base liquid, and the modified surface is removed through mechanical abrasion. The speed of rotation and pressure used in the CMP step (E4) are optimized so as to uniformly remove material from the surface of the first semiconductor layer 2 or second electrically insulating layer 2b, without however degrading the finish of the surface, and, in particular, without increasing the roughness thereof.

Alternatively, the rapid thermal annealing (E3′) is carried out at a temperature between 1100° C. and 1250° C. for a few seconds to around one hundred seconds, for example, under an atmosphere containing a mixture of hydrogen and/or argon.

Optionally, the free surface of the second semiconductor layer 3 may also be treated or functionalized depending on the targeted application.

In these various surface-treatment steps, and, in particular, in the heat-treatment steps, the oxide layer 1a very advantageously limits wafer deformation.

1. A method of fabricating a double semiconductor-on-insulator structure comprising, in succession, from a back side to a front side of the structure:
a handle substrate, a first electrically insulating layer, a first single-crystal semiconductor layer, a second electrically insulating layer and a second single-crystal semiconductor layer, the method comprising:
a first step of formation of an oxide layer on a front side and a back side of the handle substrate, to form the first electrically insulating layer on the front side of the handle substrate and an oxide layer on the back side of the handle substrate;
a first step of layer, transfer to transfer the first single-crystal semiconductor layer from a first donor substrate to the first electrically insulating layer, so as to form a first semiconductor-on-insulator substrate, comprising successively, from the back side to the front side of the first semiconductor-on-insulator substrate, the oxide layer on the back side of the handle substrate, the handle substrate, the first electrically insulating layer and the first single-crystal semiconductor layer;
a second step of formation of an oxide layer on the front side of the first semiconductor-on-insulator substrate to form the second electrically insulating layer and thicken the oxide layer on the back side of the handle substrate; and
a second step of layer, transfer to transfer the second single-crystal semiconductor layer from a second donor substrate to the second electrically insulating layer, so as to form the double semiconductor-on-insulator structure.

2. The method of claim 1, wherein a thickness of the first electrically insulating layer is between 100 nm and 3000 nm.

3. The method of claim 1, wherein a thickness of the first single-crystal semiconductor layer is between 50 nm and 500 nm in the double semiconductor-on-insulator structure.

4. The method of claim 1, wherein a thickness of the second electrically insulating layer is between 100 nm and 1100 nm in the double semiconductor-on-insulator structure.

5. The method of claim 1, wherein a thickness of the second single-crystal semiconductor layer is between 50 nm and 500 nm in the double semiconductor-on-insulator structure.

6. The method of claim 1, wherein the step of transfer of the first single-crystal semiconductor layer from the first donor substrate to the first electrically insulating layer is carried out using a process comprising, in succession, implantation of atomic species to create, within the first donor substrate, a weakened region bounding the first single-crystal semiconductor layer, bonding the side of the first donor substrate of the first single-crystal semiconductor layer that underwent implantation to the first electrically insulating layer, and splitting the first donor substrate level with the weakened region.

7. The method of claim 6, wherein a remnant of the first donor substrate resulting from splitting is used to form the second donor substrate.

8. The method of claim 6, wherein the process of transfer of the first single-crystal semiconductor layer from a first donor substrate to the first electrically insulating layer further comprises oxidation of the a surface of the first donor substrate prior to the implantation of atomic species within the first donor substrate, thus forming a first protective oxide layer so that the atomic species are implanted through the first protective oxide layer.

9. The method of claim 8, further comprising removing the first protective oxide layer formed on the surface of the first donor substrate after the atomic species have been implanted and before the first donor substrate is bonded to the first electrically insulating layer.

10. The method of claim 1, wherein the step of transfer of the second single-crystal semiconductor layer from a second donor substrate to the second electrically insulating layer is carried out using a process comprising, in succession, implantation of atomic species to create, within the second donor substrate, a weakened region bounding the second single-crystal semiconductor layer, bonding the side of the second donor substrate of the second single-crystal semiconductor layer that underwent implantation to the second electrically insulating layer, and splitting the second donor substrate level with the weakened region.

11. The method of claim 10, wherein the process of transfer of the second single-crystal semiconductor layer from a second donor substrate to the second electrically insulating layer further comprises oxidation of the surface of the second donor substrate prior to the implantation of atomic species within the second donor substrate, thus forming a second protective oxide layer so that the atomic species are implanted through the second protective oxide layer.

12. The method of claim 11, further comprising removing the second protective oxide layer formed on the surface of the second donor substrate after the atomic species have been implanted and before the second donor substrate is bonded to the second electrically insulating layer.

13. The method of claim 1, further comprising treating a surface of the first semiconductor-on-insulator substrate, before the second step of formation of an oxide layer on the surface of the first semiconductor-on-insulator substrate, the treating of the surface comprising:
a first step of rapid thermal annealing;
a second step of thermal oxidation followed by a deoxidation;
a third step of long-duration heat treatment or a third step of rapid thermal annealing, the long-duration heat treatment and the rapid thermal annealing being carried out at a temperature above 1000° C. in a non-oxidizing atmosphere; and
a fourth step of chemical-mechanical polishing.

14. The method of claim 1, wherein the handle substrate, the first donor substrate, and the second donor substrate each comprise a wafer having a diameter of 300 mm.

15. The method of claim 1, wherein the oxide layer on the back side of the handle substrate contributes to preservation of flatness of the handle substrate during the first transfer step and the second transfer step.

16. A double semiconductor-on-insulator structure, comprising, in succession from a back side to a front side of the structure:
an oxide layer having a thickness;
a handle substrate;
a first electrically insulating layer having a thickness of at least 100 nm, the thickness of the first electrically insulating layer being less than the thickness of the oxide layer;
a first single-crystal semiconductor layer having a thickness of at least 50 nm;
a second electrically insulating layer having a thickness of at least 100 nm; and
a second single-crystal semiconductor layer having a thickness of at least 50 nm.

17. The double semiconductor-on-insulator structure of claim 16, wherein the thickness of the first single-crystal semiconductor layer is less than 500 nm.

18. The double semiconductor-on-insulator structure of claim 16, wherein the thickness of the second electrically insulating layer is less than 1100 nm.

19. The double semiconductor-on-insulator structure of claim 16, wherein the thickness of the second single-crystal semiconductor layer is less than 500 nm.

20. The double semiconductor-on-insulator structure of claim 16, wherein each of the first electrically insulating layer and the second electrically insulating layer comprises an oxide layer, respectively.
